(19) United States
(12) Patent Application Publication
(10) Pub. No.: US 2019/0386163 A1
(43) Pub. Date: Dec. 19, 2019

(54) Film for photovoltaic cell and associated manufacturing method, photovoltaic cell and photovoltaic module

(71) Applicants: ARMOR, Nantes (FR); UNIVERSITÉ DE BORDEAUX, Bordeaux (FR); INSTITUT POLYTECHNIQUE DE BORDEAUX, Talence (FR); Centre national de la recherche scientifique, Paris (FR)

(72) Inventor: Uyxing VONGSAYSY, Talence (FR)

(73) Assignees: ARMOR, Nantes (FR); UNIVERSITÉ DE BORDEAUX, Bordeaux (FR); INSTITUT POLYTECHNIQUE DE BORDEAUX, Talence (FR); Centre national de la recherche scientifique, Paris (FR)

(21) Appl. No.: 16/439,043

(22) Filed: Jun. 12, 2019

(30) Foreign Application Priority Data
Jun. 13, 2018 (FR) 18 55178

(51) Int. Cl. H01L 31/05; H01L 31/0216

(52) U.S. Cl. CPC H01L 31/0512; H01L 31/02167

(57) ABSTRACT

This invention concerns a film for a photovoltaic cell comprising at least one metal oxide and at least one additive. The metal oxide has a conduction band with a minimum energy level. The additive is selected from the group consisting of alkaline hydroxides, alkaline earth hydroxides, semi-conducting materials having a highest occupied molecular orbital with an energy level with an absolute value lower than the absolute value of the minimum energy level of the conduction band of the metal oxide, and n-type doping materials having an ionization energy lower than the absolute value of the minimum energy level of the conduction band of the metal oxide.

### CROSS REFERENCE TO RELATED APPLICATION

This patent application claims the benefit of priority document FR 18 55178 filed on Jun. 13, 2018 which is hereby incorporated by reference.

### FIELD OF THE INVENTION

The present invention concerns a film for a photovoltaic cell and a method for the production of a film for photovoltaic cell. The present invention additionally relates to a photovoltaic cell including the film and a photovoltaic module including at least one photovoltaic cell that includes the film.

### BACKGROUND OF THE INVENTION

A photovoltaic cell is an electronic component that, when exposed to light (photons), produces electricity due to the photovoltaic effect obtained using the properties of semi-conducting materials.

The term ‘semiconductor’ refers to a material having the electrical characteristics of an insulator, but in which the probability that an electron may contribute to an electrical current, however weak, is non-negligible. In other words, the electrical conductivity of a semiconductor is intermediate, lying between the electrical conductivity of metals and the electrical conductivity of insulators.

The behaviour of semiconductors is described by quantum physics using an approximation based on electronic band structure. The approximation based on electronic band structure provides that an electron in a semiconductor only takes on energy values within the contiguous intervals referred to as ‘bands’, more specifically permitted bands, which are separated by other ‘bands’, which are referred to as band gaps or forbidden bands.

Two permitted energy bands play a specific role: the last completely full band, referred to as the ‘valence band’, and the subsequent permitted band, referred to as the ‘conduction band’. In a semiconductor, as with an insulator, the valence band and the conduction band are separated by a band gap, commonly referred to simply as the ‘gap’.

The breadth of this band gap delimits the minimum amount of energy that must be supplied to an electron for it to pass from a fundamental state to an excited state. The energy is provided, for example, in the form of light energy.

Semiconductors are divided into two categories that are p-type semiconductors, also referred to as electron donors, and n-type semiconductors, also referred to as electron acceptors.

In the case of an organic semiconductor, i.e. a semiconductor comprising at least one bond that is included in the group of the covalent bonds between a carbon atom and a hydrogen atom, the covalent bonds between a carbon atom and a nitrogen atom, or the bonds between a carbon atom and an oxygen atom, the electronic band structure approximation does not apply; however, by way of analogy, molecular orbitals show the same behaviour, with the HO orbital corresponding to the valence band and the LU orbital corresponding to the conduction band. The HO orbital (short for ‘higher occupied’) is also referred to as a HOMO orbital (Highest Occupied Molecular Orbital), and refers to the highest-energy molecular orbital that is occupied by at least one electron. The LU orbital (short for ‘lower unoccupied’) is also referred to as a LUMO orbital (Lowest Unoccupied Molecular Orbital), and refers to the lowest-energy molecular orbital that is not occupied by one electron.

One way of characterising the performance of a photovoltaic cell is to calculate the conversion efficiency.

The ‘conversion efficiency’ of a photovoltaic cell refers to the ratio of the maximum electrical energy at the output of the photovoltaic cell to the light energy received by the photovoltaic cell. The conversion efficiency allows for a characterization of the fraction of light energy originally captured that is injected in electrical form into the grid.

A photovoltaic cell is obtained by depositing several layers, one of which ensures the transport of electrons. This layer is the electron transport layer or ETL.

The electron transport layer is metal oxide-based. Titanium oxide (TiO₂) and zinc oxide (ZnO) are generally used to form the electron transport layer given their advantageous characteristics in the context of industrial photovoltaic cell production, such as low cost, ease of synthesis, non-toxicity, high stability, and their optical and electronic properties.

However, the use of an electron transport layer comprising a metal oxide requires ultraviolet irradiation for a certain amount of time before the photovoltaic cell will carry out its electronic functions. A photovoltaic cell only becomes fully functional once it has been exposed to light for a certain amount of time, known as the ‘photo-activation time’ or ‘activation time’.

Photo-activation times in the region of thirty minutes were reported in Lilliedal M. et al. The effect of post processing treatments on inflection points in current-voltage curves of roll-to-roll processed polymer photovoltaics’, Sol. Energy Mat. & Solar cells 94 (2010): 2018-2031. The photovoltaic cells tested include an electron transport layer obtained from a solution of zinc oxide nanoparticles. After being stored in darkness for several weeks, the photovoltaic cells are exposed to ultraviolet radiation, and the electrical efficiency of the cells are measured. It has been found that photovoltaic cells only attain their optimal conversion efficiency after a period of time in the region of thirty minutes.

Photovoltaic cells do not instantly deliver their maximum electrical power, and the wait time is a source of inconvenience for the user. Furthermore, when electrical measurements are carried out during the development or post-production monitoring of photovoltaic cells, the existence of an activation time is detrimental to measurement productivity.

### SUMMARY OF THE INVENTION

One objective of the present invention is to obtain photovoltaic cells capable of attaining maximum electrical power in a significantly shorter time, which may, in particular, be less than one minute, whilst being simple and easy to manufacture on the industrial scale.

To this end, a film for photovoltaic cell comprising at least one metal oxide and at least one additive is proposed. The metal oxide has a conduction band with a minimum energy level. The additive is selected from the group consisting of alkaline hydroxides, alkaline earth hydroxides, semi-conducting materials and n-type doping materials. Said semi-conducting materials have a highest occupied molecular orbital, said molecular orbital having an energy level with an absolute value lower than the absolute value of the minimum energy level of the conduction band of the metal oxide. The n-type doping materials have an ionization energy lower than the absolute value of the minimum energy level of the conduction band of the metal oxide.

A film for photovoltaic cell comprising at least one metal oxide and at least one additive is also proposed. The metal oxide has a conduction band with a minimum energy level. The additive is selected from the group consisting of alkaline hydroxides, alkaline earth hydroxides, and n-type semi-conducting materials. Said materials have a highest occupied molecular orbital, said molecular orbital having an energy level with an absolute value lower than the absolute value of the minimum energy level of the conduction band of the metal oxide.

Due to this film, the photovoltaic cells have a significantly shorter photo-activation time, which may be less than one minute for certain film compositions. Photovoltaic cells including such a film function without any photo-activation time or with a shorter photo-activation time whilst maintaining starting performances comparable to those of photovoltaic cells that do not comprise any additives in the electron transport layer.

In particular embodiments, the film comprises one or more of the following characteristics, taken individually or in any combination technically possible:
the film comprises at least one metal oxide, the metal oxide having a conduction band with a minimum energy level, and at least one additive, the additive being selected from the group consisting of alkaline hydroxides, alkaline earth hydroxides, n-type semi-conducting materials, and n-type doping materials, said n-type semi-conducting materials having a highest occupied molecular orbital, said molecular orbital having an energy level with an absolute value lower than the absolute value of the minimum energy level of the conduction band of the metal oxide, and the n-type doping materials have an ionization energy lower than the absolute value of the minimum energy level of the conduction band of the metal oxide;
the film consists of at least one metal oxide, the metal oxide having a conduction band with a minimum energy level, and at least one additive, the additive being selected from the group consisting of alkaline hydroxides, alkaline earth hydroxides, n-type semi-conducting materials, and n-type doping materials, said n-type semi-conducting materials having a highest occupied molecular orbital, said molecular orbital having an energy level with an absolute value lower than the absolute value of the minimum energy level of the conduction band of the metal oxide, and the n-type doping materials have an ionization energy lower than the absolute value of the minimum energy level of the conduction band of the metal oxide;
the film consists of at least one metal oxide, the metal oxide having a conduction band with a minimum energy level, and at least one additive, the additive being selected from the group consisting of alkaline hydroxides, alkaline earth hydroxides, and n-type semi-conducting materials, said materials having a highest occupied molecular orbital, said molecular orbital having an energy level with an absolute value lower than the absolute value of the minimum energy level of the conduction band of the metal oxide;
each metal oxide is chosen from zinc oxide, titanium oxide, tin oxide, derivatives and mixtures thereof;
the ratio between the additive content and the metal oxide content is less than or equal to 10.0%, preferably less than or equal to 5.0%, more preferably less than or equal to 1.0%, the additive content being defined as the sum of the amounts of each additive and the metal oxide content being defined as the sum of the amounts of each metal oxide;
the ratio between the additive content and the metal oxide content is greater than or equal to 0.01%, preferably greater than or equal to 0.025%;
each additive is a n-type dopant, said n-type dopant increasing the electron transport capacity of a doped material with said dopant compared to the electron transport capacity of an undoped material by a factor greater than or equal to 1.1;
each additive is a n-type dopant, said n-type dopant decreasing the photo-activation time of the doped material with said dopant compared to the photo-activation time of the undoped material by a factor greater than or equal to 1.1;
each additive is an alkaline hydroxide or an alkaline earth hydroxide, advantageously selected from the group consisting of sodium hydroxide, potassium hydroxide, lithium hydroxide, and barium hydroxide;
the ratio between the additive content and the metal oxide content is greater than or equal to 0.05% and less than or equal to 1.0%, the additive content being defined as the sum of the amounts of each additive and the metal oxide content being defined as the sum of the amounts of each metal oxide;
the additive is decamethyl cobaltocene;
the film has a thickness comprised between 30 nanometers and 100 nanometers, preferably between 30 nanometers and 60 nanometers, more preferably between 35 nanometers and 45 nanometers.

Also proposed is a method for producing a film for photovoltaic cell comprising a step of preparing a mixture comprising at least one metal oxide, the metal oxide having a conduction band with a minimum energy level, and at least one additive, the additive being chosen from the group consisting of alkaline hydroxides, alkaline earth hydroxides, semi-conducting materials, and n-type doping materials, said semi-conducting materials having a highest occupied molecular orbital, said molecular orbital having an energy level with an absolute value lower than the absolute value of the minimum energy level of the conduction band of the metal oxide, and said n-type doping materials having an ionization energy lower than the absolute value of the minimum energy level of the conduction band of the metal oxide. The method further comprises a step of coating the mixture onto a substrate to form the film, the substrate being preferably an electrode made in an indium-tin alloy.

Also proposed is a method for producing a film for photovoltaic cell comprising a step of preparing a mixture comprising at least one metal oxide, the metal oxide having a conduction band with a minimum energy level, and at least one additive, the additive being chosen from the group consisting of alkaline hydroxides, alkaline earth hydroxides and n-type semi-conducting materials, said n-type semi-conducting materials having a highest occupied molecular orbital, said molecular orbital having an energy level with an absolute value lower than the absolute value of the minimum energy level of the conduction band of the metal oxide. The method further comprises a step of coating the mixture onto a substrate to form the film, the substrate being preferably an electrode made in an indium-tin alloy.

In particular embodiments, the method comprises one or more of the following characteristics, taken individually or in any combination technically possible:
the method comprises a step of preparing a mixture comprising at least one metal oxide, the metal oxide having a conduction band with a minimum energy level, and at least one additive, the additive being chosen from the group consisting of alkaline hydroxides, alkaline earth hydroxides, n-type semi-conducting materials, and n-type doping materials, said n-type semi-conducting materials having a highest occupied molecular orbital, said molecular orbital having an energy level with an absolute value lower than the absolute value of the minimum energy level of the conduction band of the metal oxide, and said n-type doping materials having an ionization energy lower than the absolute value of the minimum energy level of the conduction band of the metal oxide, the method further comprising a step of coating the mixture onto a substrate to form the film, the substrate being preferably an electrode made in an indium-tin alloy;
the method comprises a single step of heating following the step of coating;
the single heating step has a duration that is less than or equal to 5 minutes, the duration is preferably greater than or equal to 2 minutes, the temperature at which the single heating step is carried out is preferably constant, for example constant at a temperature greater than or equal to 100° C. and less than or equal to 140° C., preferably equal to 120° C.

Also proposed is a photovoltaic cell comprising a film as defined above.

In one particular embodiment, the photovoltaic cell comprises the characteristic that the film is coated onto an electrode consisting of a conducting material selected, in particular, from a silver nanoparticle-based ink, a silver nanowire-based ink, an indium oxide-tin alloy, and a mixture thereof.

Also proposed is a photovoltaic module including at least one cell as defined above.

### BRIEF DESCRIPTION OF THE FIGURES

Other characteristics and advantages of the invention will be seen from the following description of embodiments of the invention, provided by way of example only, by reference to the attached figures:

FIG. 1 is a schematic sectional view of a photovoltaic cell according to a first embodiment;

FIG. 2 is a graph showing the development of current-voltage curves as a function of the light exposure time for a photovoltaic cell having an electron transport layer consisting of zinc oxide;

FIG. 3 is a graph showing the development of current-voltage curves as a function of the light exposure time for a photovoltaic cell comprising a first additive in its electron transport layer, according to Experiment 1;

FIG. 4 is a graph showing the development of current-voltage curves as a function of the light exposure time for a photovoltaic cell comprising a second additive in its electron transport layer, according to Experiment 4;

FIG. 5 is a graph showing the development of the electrical conversion efficiency (ECE) of the photovoltaic cell of FIG. 1 as a function of the time spent in a weathering tester (continuous light irradiation at 1000 W/m² with a xenon lamp at a temperature of 50° C., humidity not controlled), referred to as the ‘photo-degradation time’, according to Experiment 2.

### DESCRIPTION OF EMBODIMENTS OF THE INVENTION

A photovoltaic module (not shown) is a device suited to convert solar energy received into electrical energy.

The photovoltaic module includes at least two photovoltaic cells 8 that are connected in series or in parallel.

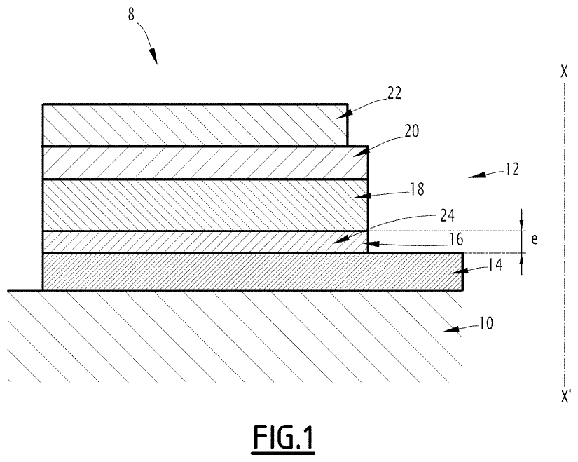

A photovoltaic cell 8 according to a first embodiment is shown in FIG. 1.

The photovoltaic cell 8 has a substrate 10.

The substrate 10 is a planar layer. A stacking direction represented by XX′ in FIG. 1 and normal to the substrate 10 is defined. The stacking direction is thus referred to in the following simply as the stacking direction XX′.

Advantageously, the substrate 10 is a flexible substrate made of plastic material, e.g. PET (polyethelene terephthalate) or PEN (polyethylene naphthalate).

The photovoltaic cell 8 includes a stack 12 of five planar layers 14, 16, 18, 20, 22, superimposed along the stacking direction XX′.

The stack 12 includes a first electrode 14, an electron transport layer 16, an active layer 18, a hole conducting layer 20, and a second electrode 22.

The first electrode 14, also referred to as the ‘lower electrode’, is in contact with the substrate 10.

The first electrode 14 is transparent at least to visible light, i.e. radiation having a wavelength in a vacuum between 380 nanometers and 900 nanometers.

The first electrode 14 is made of a conductive material. The conductive material is selected, e.g., from a silver nanoparticle-based ink, a silver nanowire-based ink, an indium-tin oxide alloy (‘ITO alloy’), and a mixture thereof.

A nanoparticle is defined as a particle in which each dimension is between 1 and 100 nanometers.

A nanowire is defined as a wire having a diameter with a maximum dimension between 1 and 100 nanometers that extends in a direction normal to this diameter.

The electron transport layer 16 is located between the first electrode 14 and the active layer 18. The electron transport layer 16 is intended to ensure the transport of electrons between the active layer 18 and the first electrode 14.

The electron transport layer 16 and its composition will be described in greater detail below.

The active layer 18 is located between the electron transport layer 16 and the hole conducting layer 20.

The active layer 18 comprises a mixture of semi-conducting materials. The active layer 18 consists of a mixture of an electron donor material (‘p-type material’) and an electron acceptor material (′n-type material).

For example, the electron donor is selected from:
P3HT (poly(3-hexylthiophene-2,5-diyl),
PBDTTT-C-T Cpoly((4,8-bis-(2-ethyl-hexyl-thiophene-5-yl)-benzo(1,2-b:4,5-b′)dithiophene-2,6-diyl)-alt-(2-(2′-ethyl-hexanoyl)-thieno(3,4-b)thiophen-4,6-diyl))),
PBDTTT-CF (poly[4,8-bis(2-ethylhexyloxy)-benzo[1,2-b:4,5-b]dithiophene-2,6-diyl-alt-(4-octanoyl-5-fluoro-thieno[3,4-b]thiophene-2-carboxylate)-2,6-diyl]),
PCDTBT (poly[N-9′-heptadecanyl-2,7-carbazole-alt-5,5-(4′,7′-di-2-thienyl-2′,1′,3′-benzothiadiazole)]),
MEH-PPV (poly[2-methoxy-5-(2-ethylhexyloxy)-1,4-phenylenevinylene]),
PTB7 (poly[[4,8-bis[(2-ethylhexyl)oxy]benzo[1,2-b:4,5-b]dithiophene-2,6-diyl][3-fluoro-2-[(2-ethylhexyl)carbonyl]thieno[3,4-b]thiophenediyl]]),
PTB7-Th (thiophenated-PTB7),
PT8 (poly-benzodithiophene-N-alkylthienopyrroledione), and
PFN (poly[(9,9-bis(3′-(N, N-dimethylamino)propyl)-2,7-fluorene)-alt-2,7-(9,9-dioctylfluorene)]).

For example, the electron acceptor is selected from fullerene, [6,6]-phenyl-061-methyl butyrate (also known as PC60BM), [6,6]-phenyl C61-butyric acid methyl ester (also known as C60-PCBM), [6,6]-phenyl C71-butyric acid methyl ester (also known as C70-PCBM), bis(1-[3-(methoxycarbonyl)propyl]-1-phenyl)[6,6]C62 (also known as Bis-C60-PCBM), 3′phenyl-3′H-cyclopropa[8,25][5,6]fullerene-C70-bis-D5h(6)-3′butanoic acid methyl ester (also known as Bis-070-PCBM), indene-C60-bisadduct (also known as ICBA), mono indene nil C60 (ICMA), and non-fullerene acceptors such as indacenodithiophene derivatives, indenofluorene derivatives, fluorene derivatives, perylene derivatives, and diimide derivatives.

In a particular embodiment, the active layer 18 comprises several electron acceptor materials and/or several electron donor materials. For example, the active layer 18 is a ternary mixture comprising one electron donor material and two electron acceptor materials or a ternary mixture comprising two electron donor materials and one electron acceptor material.

The hole conducting layer 20 is located between the active layer 18 and the second electrode 22.

The hole conducting layer 20 is intended to ensure the transport of holes between the active layer 18 and the first electrode 22.

The hole conducting layer 20 is made of a semi-conductive material or a mixture of semi-conductive materials. Preferably the mixture of conductive materials is a mixture of poly(3,4-ethylenedioxythiophene) and sodium polystyrene sulphonate, also referred to as a PEDOT:PSS mixture.

The second electrode 22, also referred to as the ‘upper electrode’, extends at least partially over the hole conducting layer 20.

The second electrode 22 is made of a conductive material. The conductive material is selected, for example, from a silver-based link, a silver nanoparticle-based ink, a silver nanowire-based ink, and a mixture thereof.

The electron transport layer 16 is produced by coating a film 24.

A film is defined as a continuous, homogeneous layer consisting of one material or a mixture of materials.

The film 24 has a thickness e. The thickness e is the dimension of the film 24 in the stacking direction XX′ measured using a mechanical profilometer.

The thickness e of the film 24 is relatively low. A ‘relatively low thickness’ refers to a thickness less than or equal to 500 microns.

Preferably, the thickness e of the film 24 is between 30 nanometers and 100 nanometers. The thickness e of the film 24 is sufficient to avoid the risk of short circuits and low enough to avoid decreases in the electrical efficiency of the photovoltaic cell 8 due to the series resistance of the photovoltaic cell 8.

Advantageously, the thickness e of the film 24 is between 30 nanometers (nm) and 60 nanometers, advantageously between 35 nanometers and 45 nanometers.

For example, the thickness e of the film 24 is 40 nanometers.

The composition of the film 24, shown in FIG. 1, will now be described.

The film 24 comprises at least one metal oxide and at least one additive.

Preferably, the film 24 consists of at least one metal oxide and at least one additive.

The metal oxide includes a valence band and a conduction band. The conduction band has a minimum energy level.

The minimum energy level of the conduction band is defined as being, from among the energy bands allowed for an electron in the metal oxide, the energy of the band that has the lowest energy while not being filled at a temperature inferior or equal to 20 K.

The metal oxide is selected from the group consisting of zinc oxide (ZnO), titanium oxide (TiO₂), tin oxide (SnO₂), and derivatives thereof.

‘Metal oxide derivative’ refers to a metal oxide that has been subjected to doping. Derivatives include, e.g., antimony-doped tin oxide or aluminium-doped zinc oxide (AZO).

In a particular case, the metal oxide is ZnO or TiO₂.

In the example proposed, the film 24 comprises a single metal oxide.

Only the embodiment in which the film 24 comprises a single metal oxide is described in detail below. However, in one variant, the film 24 comprises a mixture of several metal oxides in lieu of a single metal oxide. For example, the film 24 comprises an equimolar mixture of zinc oxide and tin oxide.

In the example proposed, the film 24 comprises a single additive.

The additive is a chemical compound that does not belong to the class of metal oxides.

In the first embodiment, the additive is selected from the group of alkaline hydroxides and alkaline earth hydroxides.

An alkaline hydroxide or alkaline metal hydroxide is a chemical compound having an alkaline metal cation and a hydroxide anion (HO—). Alkaline hydroxides include lithium hydroxide, sodium hydroxide, potassium hydroxide, rubidium hydroxide, caesium hydroxide, and francium hydroxide.

An alkaline earth hydroxide or alkaline earth metal hydroxide is a chemical compound having an alkaline earth metal cation and a hydroxide anion (HO—). Alkaline earth hydroxides include beryllium hydroxide, magnesium hydroxide, calcium hydroxide, strontium hydroxide, barium hydroxide, and radium hydroxide.

For example, the additive is chosen from the group consisting of lithium hydroxide, sodium hydroxide, potassium hydroxide, and barium hydroxide.

The ratio between the additive content and the metal oxide content, or ‘molar additive:metal oxide ratio’ or ‘additive:metal oxide ratio’ is the mathematical ratio in which the numerator is the amount of additive and the denominator is the amount of metal oxide.

The ratio between the additive content and the metal oxide content is less than or equal to 10.0%.

Preferably, the ratio between the additive content and the metal oxide content is less than or equal to 5.0%, advantageously less than or equal to 1.0%, preferably less than or equal to 0.5%, more preferably less than or equal to 0.1%.

The ratio between the additive content and the metal oxide content is greater than or equal to 0.01%, advantageously greater than or equal to 0.025%, preferably greater than or equal to 0.05%.

The operation of the photovoltaic module will now be explained.

Light radiation reaches the photovoltaic module at the level of one or more photovoltaic cells 8. Photons are absorbed at the active layer 18. The energy of the photons is transferred to electrons of the active layer 18. Electron-hole pairs are thus generated before experiencing disjunction.

The electron transport layer 16 and the hole conducting layer 20 facilitate the disjunction of electron-hole pairs.

The hole conducting layer 20 ensures the transport of holes from the active layer 18 to the second electrode 22, which acts as the anode. The electron transport layer 16 ensures the transport of electrons from the active layer 18 to the first electrode 14, which acts as the cathode.

The presence of the additive in the electron transport layer 16 reduces its resistivity, thus facilitating the transport of electrons to the first electrode 14. However, there is to date no test that allows this decrease in resistivity to be measured.

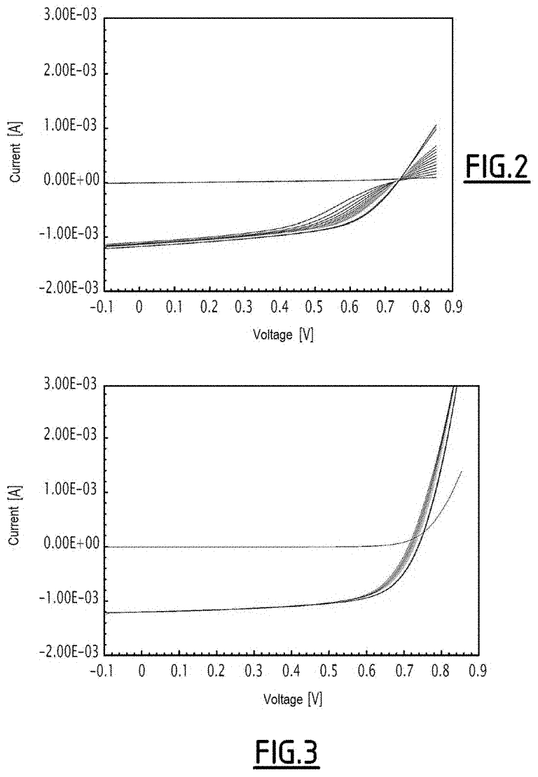

A photovoltaic cell having an electron transport layer with no additive has high resistivity. This property can be seen, in particular, in FIG. 2 from the presence of an S-shaped current-voltage curve. The resistivity of the electron transport layer decreases when the photovoltaic cell is exposed to light radiation for an increasing duration: At the end of the photo-activation time, the current-voltage curve is no longer S-shaped.

The current-voltage curve of the photovoltaic cell 8 of the first embodiment, comprising sodium hydroxide as an additive in a molar ratio NaOH:ZnO of 2.0%, is shown in FIG. 3. The curve is not S shaped, no matter the amount of time for which the photovoltaic cell 8 is exposed to light radiation. The absence of an S shape confirms the greater conductivity of the electron transport layer 16 comprising an additive compared to an electron transport layer with no additive.

Following the movement of the electrons and holes to the cathode and anode, respectively, a potential difference appears between the two electrodes 14, 22, and the photovoltaic cells 8 produce direct electrical current. The photovoltaic cells 8 are connected by means of junctions to form photovoltaic modules that provide electrical energy to an external electrical circuit.

The photovoltaic cell 8 is electrically characterised by placing the photovoltaic cell 8 under continuous light irradiation. Current-voltage curves are obtained from current-voltage measurements, and photovoltaic parameters such as short-circuit current J_{cc}, open circuit voltage V_{co}, form factor FF; and electrical conversion efficiency PCE are extracted.

The electrical measurements are carried out at different time intervals, e.g. an interval of three seconds.

One of the discriminating photovoltaic parameters in the activation of a photovoltaic cell 8 is the form factor FF. The form factor FF depends on the charge extraction capacity of the electrodes. The percent variation in form factor (% variation FF) is measured by the following formula:

$$\% variation F F = \frac{F F ( t + 3 s ) - F F ( t )}{F F ( t )} * 100$$

where: ●FF(t) is the form factor at a given point in time t, and
●FF(t+3 sec) is the form factor at t+3 seconds.

The activation time is set as the time before the percent variation in form factor falls below 0.1%.

Photovoltaic cells 8 comprising the film 24 have a significantly shorter photo-activation time, which may be less than one minute for certain compositions. Experiment 1 details the electrical efficiency of photovoltaic cells 8 according to the first embodiment.

The conversion efficiency of the cells 8 comprising the film 24 reaches its maximum value in much less time; the time may be, in particular, less than one minute for certain compositions.

Photovoltaic cells 8 according to the first embodiment function without any photo-activation time or with a shorter photo-activation time whilst maintaining starting performances comparable to those of photovoltaic cells that do not comprise any additives in the electron transport layer.

Additionally, after several hours of continuous light exposure, the photovoltaic cells 8 show electrical performances similar to those of a photovoltaic cell comprising no additive in the electron transport layer. The stability of the film 24 is not reduced compared to a film not comprising an additive, as can be seen from the results of Experiment 2, described in detail below.

On the other hand, following several hours of exposure at temperatures of 50 and 85° C. (thermal degradation tests), the photovoltaic cells 8 show electrical performances similar to those of photovoltaic cells that have not been thermally degraded. Thus, the addition of an additive does not result in any thermal degradation of the photovoltaic performance of the photovoltaic cells. These results are shown in Experiment 3.

The photovoltaic cells 8 are easy to manufacture, making them particularly suited to large-scale production.

A method for producing a film 24 for a photovoltaic cell 8 according to this first embodiment will now be described.

The production method comprises a step of preparing a mixture comprising the metal oxide and the additive and a step of coating the mixture onto a substrate to form the film 24.

Metal oxide nanoparticles are suspended in a solvent. The metal oxide is selected from the group consisting of zinc oxide (ZnO), titanium oxide (TiO₂), tin oxide (SnO₂), and derivatives thereof.

The solvent preferably contains no halogen compound, particularly chlorinated compounds.

Advantageously, the solvent has an autoignition temperature greater than 200° C. The solvent is compatible with the use of a thermal drier.

The solvent can thus be used in an industrial context, and limits the risks for worker health and the environment.

The method for producing the film 24 further includes a step of adding the additive to the solution containing the metal oxide nanoparticles.

Preferably, the additive is solubilised with the aid of ultrasound or by mechanical agitation with a bar magnet.

In another embodiment, the mixture is obtained by the sol-gel method. A precursor of the metal oxide is placed in contact with a basic catalyst in a solvent. The precursor undergoes a hydrolysis reaction, followed by a condensation reaction, to form oligomeric clusters. The clusters are then dispersed in a solution to form a sol to which the additive is added.

For example, the metal oxide precursor is zinc acetate dehydrate, the basic catalyst is monoethanolamine, and the solvent is absolute ethanol. The zinc acetate dihydrate solution in the presence of monoethanolamine in the absolute ethanol is agitated at 45° C. for two hours, then each additive is added to form the mixture comprising the metal oxide and the one or more additives.

A mixture comprising the metal oxide and the additive is obtained.

The method for producing the film 24 also comprises a step of coating or depositing the mixture deposited on a substrate by liquid means to form a film 24.

The mixture is deposited by a technique selected from the group of coating or printing techniques. For example, the mixture is deposited on the substrate by a technique chosen from the group of roll-to-roll coating or printing techniques, spinner deposition, knife coating, slot-die coating, screen printing, flexography, and inkjet methods.

In the following, the term ‘coating’ includes the aforementioned coating and printing techniques.

Preferably, the substrate is an electrode consisting of a conductive material selected, e.g., from a silver nanoparticle-based ink, a silver nanowire-based ink, an indium-tin oxide alloy, and a mixture thereof.

Advantageously, the method further comprises a single step of heating following the step of coating. The heating step facilitates the evaporation of the solvent.

For example, the heating step is carried out using a hot plate in an open area.

Preferably, the heating step has a duration less than or equal to 5 minutes, advantageously less than or equal to 2 minutes.

The heating step is carried out at a constant temperature.

Preferably, the single heating step is carried out at a constant temperature greater than or equal to 100° C. and less than or equal to 130° C. For example, the single heating step is carried out at a constant temperature equal to 120° C.

Advantageously, the heating step is carried out at a constant temperature equal to 120° C. for a duration less than or equal to 2 minutes.

In one variant, the heating step comprises a first heating sub-step, a second sub-step in which the heating is interrupted, and a third heating sub-step. Preferably, the duration of the second sub-step is such that the temperature of the film 24 during this step is greater than the temperature of the film 24 before the start of the heating step.

The total duration of the heating step is less than or equal to 5 minutes, preferably less than or equal to 2 minutes.

The production method includes no long, energy-intensive annealing steps.

A film 24 having a thickness of less than 100 nm is obtained.

In one variant, the additive is selected from the group of n-type semiconductors.

n-type semiconductors have highest occupied molecular orbital or HOMO. The HOMO orbital has an energy level.

Preferably, the absolute value of the energy level of the HOMO of the organic n-type semiconductor is lower than the absolute value of the minimum energy level of the conduction band of the metal oxide.

The n-type semi-conducting material is selected from the group consisting of cobaltocene, decamethyl-cobaltocene, bis(rhodocene) and tetrakis(hexahydropyrimidinopyrimidine)ditungstene, derivatives and mixtures thereof.

In other words, the n-type semi-conducting material is selected from the group consisting of CoCp₂, du (RhCp₂)₂, du W₂(hpp)₂, derivatives and mixtures thereof.

Preferably, the n-type semi-conducting material is decamethyl cobaltocene.

The ratio between the additive content and the metal oxide content is less than or equal to 10.0%.

Preferably, the ratio between the additive content and the metal oxide content is less than or equal to 5.0%, advantageously less than or equal to 1.0%, more preferably less than or equal to 0.5%.

The ratio between the additive content and the metal oxide content is greater than or equal to 0.01%, preferably greater than or equal to 0.025%.

The electrical performance of photovoltaic cells 8 comprising decamethyl cobaltocene in the electron transport layer has been measured, and is discussed in detail in Experiment 4 below.

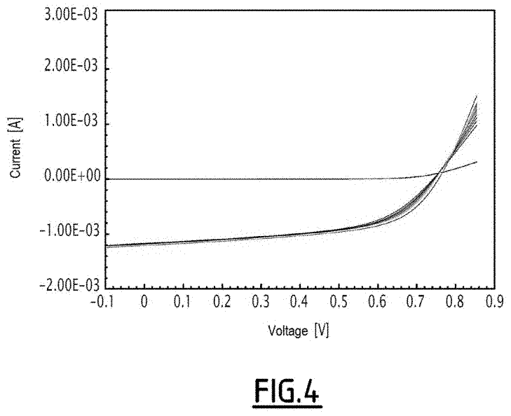

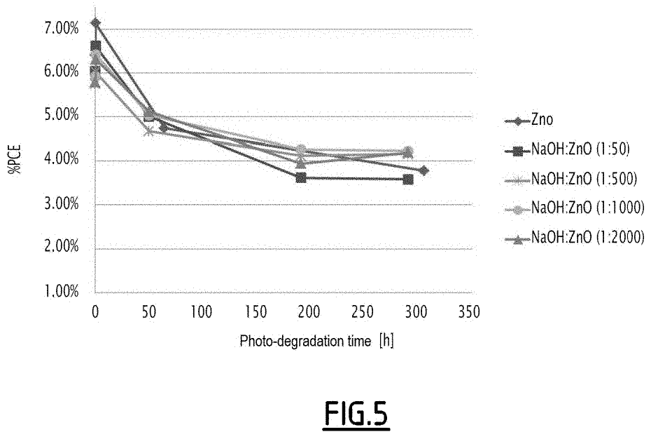

The current-voltage curve of the photovoltaic cell 8 of the first embodiment, comprising decamethyl cobaltocene as an additive in a molar ratio decamethyl cobaltocene:ZnO of 0.02%, is shown in FIG. 4. The curve is not S shaped, no matter the amount of time for which the photovoltaic cell 8 is exposed to light radiation. The absence of an S shape confirms the greater conductivity of the electron transport layer 16 comprising an additive compared to an electron transport layer with no additive.

In one variant, the film includes a mixture of additives selected from the group consisting of alkaline hydroxides, alkaline earth hydroxides, and n-type semiconducting materials, said materials having a highest occupied molecular orbital, said molecular orbital has an energy level with an absolute value of less than the absolute value of the minimum energy level of the conduction band of the metal oxide.

According to another embodiment, the additive is selected among the n-type doping materials.

For the following, the term “n-type dopant” is used to define a n-type doping material. A n-type dopant enables, when said n-type dopant is mixed with an undoped material, to obtain a doped material.

The presence of a n-type dopant increases the electron density of the doped material in comparison with the electron density of the undoped material.

The electron density of the undoped material is comprised between 10¹⁰ cm⁻³ and 10²⁰ cm⁻³, while the electron density of the doped material is comprised between 1.1·10¹⁰ cm⁻³ and 10²⁵ cm⁻³.

The electron density of the doped material is increased by at least 10% compared to the electron density of the undoped material.

For example, the electron density of the doped material is determined for a doped material obtained from a mixture comprising an undoped material and a n-type dopant. The ratio between the n-type dopant content and the undoped material content is greater than or equal to 10%.

For example, the electron density of the doped material and the undoped material is determined at a temperature of 300 K.

According to a specific example, the n-type dopant is a n-type dopant increasing the electron transport capacity of the doped material compared to the electron transport capacity of the undoped material.

The electron transport capacity is defined by the following formula:

$$σ = \frac{I \times L}{U \times S}$$

where: σ is the electron transport capacity of the material,
I is the intensity flowing through the material,
L is the length of the material,
U is the voltage applied between two points of the material separated by a distance L, and
S is the cross-section of the material.

For example, the value of the electron transport capacity of a material is determined using a device comprising a layer made of said material of a thickness L and extending over a surface area S, located between an electrode comprising indium-tin oxide and an electrode comprising aluminum. The current-voltage curve of the device is then determined. This curve is considered as a straight line, and the slope of this straight line corresponds to the term L/σ×S of the previous equation.

In particular, the thickness L of the layer is equal to 150 nanometers (nm) and the surface area S of the layer is equal to 10.5 square millimeters (mm²).

According to a specific embodiment, the material is a doped material or an undoped material.

According to another example, the value of the electron transport capacity of a material is determined by the Van der Pauw method.

According to another example, the value of the electron transport capacity of a material is determined by the four-point probe method.

For the following, a factor greater than or equal to a value X is defined as the fact that the ratio between the value of a physical parameter of a doped material and the value of the same physical parameter of an undoped material is greater than or equal to X.

Preferably, the n-type dopant is a n-type dopant increasing the electron transport capacity of the doped material compared to the electron transport capacity of the undoped material by a factor greater than or equal to 1.1.

According to another particular example, the n-type dopant is a n-type dopant decreasing the photo-activation time of the doped material compared to the photo-activation time of the undoped material.

Such a decrease in the photo-activation time is determined by comparison of the photo-activation time of a photovoltaic cell comprising an electron transport layer in the form of a film comprising at least one doped material with the photo-activation time of a photovoltaic cell comprising an electron transport layer in the form of a film comprising at least one undoped material.

To this end, the photovoltaic cell is electrically characterized by placing the photovoltaic cell under continuous light irradiation. Current-voltage curves are obtained from current-voltage measurements and photovoltaic parameters such as short-circuit current J_{cc}, open circuit voltage V_{co}, form factor FF; and electrical conversion efficiency PCE are extracted.

The electrical measurements are carried out at different time intervals, for example an interval of three seconds.

The form factor FF depends on the charge extraction capacity of the electrodes. The percent variation in form factor (% variation FF) is measured by the following formula:

$$\% variation F F = \frac{F F ( t + 3 s ) - F F ( t )}{F F ( t )} * 100$$

where: FF(t) is the form factor at a given point in time t, and
FF(t+3 sec) is the form factor at t+3 seconds.

The activation time is set as the time before the percent variation in form factor falls below 0.1%.

According to a specific example, the material is a doped material or an undoped material.

Preferably, the n-type dopant is a n-type dopant decreasing the photo-activation time of the doped material compared to the photo-activation time of the undoped material by a factor greater than or equal to 1.1.

For example, the photo-activation time of the doped material is determined for a doped material obtained from a mixture comprising an undoped material and a n-type dopant. The ratio between the n-type dopant content and the undoped material is greater than or equal to 10%.

The n-type dopants have an ionization energy lower than the absolute value of the maximal energy level of the conduction band of the metal oxide.

The term ‘ionization energy’ refers to the energy that must be provided to a neutral atom in a gaseous state of the n-type dopant to remove one electron and to form a positive ion.

In some cases, the ionization energy of the n-type dopant is defined as the energy of the highest occupied molecular orbital of the n-type dopant.

Indeed, usually, for an inorganic material, the terms ‘minimum conduction band’ and ‘maximum valence band’ are used, whereas, for an organic material, the terms ‘lowest unoccupied molecular orbital’ and ‘highest occupied molecular orbital’ are generally used.

In addition, the energy levels of the minimum conduction band and the lowest unoccupied molecular orbital are defined by the electronic affinity.

Also, the energy levels of the maximum valence band and the highest occupied molecular orbital are defined by the ionization energy.

According to a specific example, the n-type dopant is a n-type semi-conducting material. The skilled person will understand that the term “n-type semi-conducting material” is given as an example and that the invention can be apply to any type of semi-conducting material.

For example, the n-type dopants are aromatic compounds comprising at least one sulphur atom.

The aromatic compounds comprising at least one sulphur atom are selected from the group consisting of bis(ethylenedithio)-tetrathiafulvalene (BET-TTF) and tetrathianaphthacene (TTN).

According to another example, the n-type dopants are selected from the group consisting of rhodium complexes, tungsten complexes and cobalt complexes.

The rhodium complexes, tungsten complexes and cobalt complexes comprise at least one metal selected from the group consisting of rhodium, tungsten and cobalt, and at least one organic ligand comprising at least one cyclopendienyl unit, possibly substituted, or at least one heterocyclic unit, possibly substituted, comprising at least a nitrogen atom.

Preferably, the organic ligand is selected from the group consisting of cyclopentadienyl, pentamethylcyclopentadienyl and hexahydropyrimidinopyrimidine (hpp).

According to a specific example, the n-type dopants are selected from the group consisting of cobaltocene, decamethyl-cobaltocene, bis(rhodocene) and tetrakis(hexahydropyrimidinopyrimidine)ditungsten, derivatives and mixtures thereof.

As a variant or in addition, the n-type dopants are not selected from the group consisting of titanium oxide, zinc oxide, tin oxide, silicium oxide and aluminum oxide.

In some cases, the n-type dopants do not belong to the class of metal oxides.

According to a specific example, the undoped material is a metal oxide.

The metal oxide includes a valence band and a conduction band. The conduction band has a minimum energy level.

The metal oxide is selected from the group consisting of zinc oxide (ZnO), titanium oxide (TiO₂), tin oxide (SnO₂), and derivatives thereof.

In a particular case, the metal oxide is ZnO or TiO₂.

The ratio between the n-type dopant content and the undoped material content is the mathematical ratio in which the numerator is the amount of n-type dopant and the denominator is the amount of undoped material.

The ratio between the n-type dopant content and the undoped material content is less than or equal to 10.0%.

Preferably, the ratio between the n-type dopant content and the undoped material content is less than or equal to 5.0%, advantageously less than or equal to 1.0%, preferably less than or equal to 0.5%, more preferably less than or equal to 0.1%.

The ratio between the n-type dopant content and the undoped material content is greater than or equal to 0.01%, advantageously greater than or equal to 0.025%, preferably greater than or equal to 0.05%.

According to another embodiment, the film comprises a compound selected from the group consisting of Na₂₋ₓHₓTi₂O₄(OH)₂ and K₂TiO₃, x being a number greater than or equal to 0 and strictly less than 2.

In all of the foregoing variants, the photovoltaic cell 8 provides maximum electrical power faster than a photovoltaic cell that does not comprise an additive in the electron transport layer.

### EXPERIMENTS

Each of Experiments 1-4 was conducted at the Integration du Matériau au Systeme (IMS) laboratory. In particular, the scientific equipment of this laboratory was used. The IMS laboratory belongs to the research unit UMR 5218 and is located in Talence (post code 33405) in France.

Experiments 1-4 were conducted on photovoltaic cells 8 comprising a film 24 for a photovoltaic cell 8 comprising at least one metal oxide in order to determine the effect of the addition of an additive to the film 24 on the performance of the photovoltaic cells 8.

In the experiments conducted, certain parameters remained constant:
the surface area of the photovoltaic cells 8 is 10.5 mm²;
the substrate 10 consists of glass;
the lower electrode 14 consists of a layer comprising an ITO alloy;
the active layer 18 consists of a mixture of a donor-type organic semiconductor, more specifically a donor polymer with a low gap, i.e. a conjugated polymer having a gap in which the associated energy is less than 1.5 eV (electron volts), and of an acceptor-type organic semiconductor, more specifically a PCBM acceptor;
the hole conducting layer 20 consists of a mixture of poly(3,4-ethylenedioxythiophene) and poly(styrene sodium sulphonate (PEDOT:PSS);
the upper electrode 22 consists of a silver layer;
the film 24 is prepared from a nanoparticulate zinc oxide formulation;
the electron transport layer 16 is obtained by spin coating the film 24 consisting of zinc oxide and an additive;
the film 24 is deposited at an ambient temperature of 20° C.;
once it has been deposited, the film 24 has a thickness of 40 nm;
the film 24 is heated only once at 120° C. for a period of 2 minutes;
the photovoltaic cell 8 is irradiated with a metal halide lamp;
the electrical measurements are conducted in an inert atmosphere in a glove box, and
a filter blocking wavelengths below 400 nm is placed between the lamp that irradiates at 700 W/m² and the photovoltaic cell 8 in order to reproduce conditions close to the actual conditions of use of photovoltaic cells.

### Experiment 1

In Experiment 1, a photovoltaic cell 8 according to the first embodiment is produced. Several additives were tested in increasing proportions in Experiments 1a, 1b, and 1c.

### Experiment 1a

The results obtained with sodium hydroxide as the additive are shown in the table below.

| | Photo- | | | | |
|---|---|---|---|---|---|
| Molar ratio | activation | | | | |
| NaOH:ZnO | time | Jcc | Vco | | PCE |
| [%] | [s] | [mA/cm²] | [V] | FF | [%] |
| 0 | 93 | 14.26 | 0.74 | 0.60 | 6.32 |
| 0.1 | 93 | 12.82 | 0.73 | 0.57 | 5.38 |
| 0.2 | 81 | 13.16 | 0.74 | 0.58 | 5.85 |
| 1.0 | 36 | No data available | | | |
| 2.0 | 0 | 13.16 | 0.75 | 0.65 | 6.38 |

### Experiment 1 b

The results obtained with lithium hydroxide as the additive are shown in the table below.

| | Photo- | | | | |
|---|---|---|---|---|---|
| Molar ratio | activation | | | | |
| LiOH:ZnO | time | Jcc | Vco | | PCE |
| [%] | [s] | [mA/cm²] | [V] | FF | [%] |
| 0 | 93 | 14.26 | 0.74 | 0.60 | 6.32 |
| 0.05 | 24 | 12.64 | 0.80 | 0.56 | 5.71 |
| 0.10 | 27 | 12.33 | 0.80 | 0.56 | 5.54 |
| 2.00 | 3 | 12.09 | 0.80 | 0.57 | 5.48 |

### Experiment 1c

The results obtained with barium hydroxide as the additive are shown in the table below.

| | Photo- | | | | |
|---|---|---|---|---|---|
| Molar ratio | activation | | | | |
| BaOH:ZnO | time | Jcc | Vco | | PCE |
| [%] | [s] | [mA/cm²] | [V] | FF | [%] |
| 0 | 93 | 14.26 | 0.74 | 0.60 | 6.32 |
| 0.05 | 30 | 12.24 | 0.80 | 0.56 | 5.46 |
| 0.10 | 39 | 12.36 | 0.79 | 0.56 | 5.53 |
| 2.00 | 3 | 12.23 | 0.78 | 0.56 | 5.31 |

It can be seen that, for molar ratios of additive to metal oxide between 0.05 and 2.00%, the photovoltaic cells 8 according to the first embodiment have a photo-activation time of less than 1 minute no matter what additive is selected.

The other electrical parameters of the photovoltaic cell 8, i.e. short circuit current J_{cc}, open circuit voltage V_{co}, form factor FF, and electrical conversion efficiency PCE have values comparable to those obtained with a photovoltaic cell having an electron transport layer that consists solely of zinc oxide.

### Experiment 2

Photo-degradation tests are conducted on a photovoltaic cell 8 as in Experiment 1a.

Photovoltaic cells 8 having an electron transport layer 16 that does or does not include sodium hydroxide are irradiated with calibrated light (continuous light irradiation at 1000 W/m² with a xenon lamp at a temperature of 50° C., humidity not controlled) at a temperature of 50° C. in a weathering tester. The weathering tester accelerates the degradation kinetics of the components of the photovoltaic cell 8.

The electrical conversion efficiency of the photovoltaic cells 8 comprising additives in varying proportions is measured at intervals of several hours.

The results are shown in FIG. 5. The results obtained show that the electrical conversion efficiency of the photovoltaic cells 8 comprising sodium hydroxide in the electron transport layer 16 is comparable to the electric conversion efficiency of a photovoltaic cell having an electron transport layer consisting of zinc oxide.

Similar results are obtained when the sodium hydroxide is replaced with barium hydroxide, lithium hydroxide, or decamethyl cobaltocene.

It can be seen that the addition of an additive to the electron transport layer 16 does not increase the photo-degradation kinetics of the photovoltaic cell 8.

### Experiment 3

Thermal stability and dark storage tests are conducted on a photovoltaic cell 8 as in Experiment 1a.

Photovoltaic cells 8 having electron transport layers 16 comprising sodium hydroxide in a molar ratio NaOH:ZnO equal to 2.0% were subjected to dark storage at ambient temperature (approximately 25° C.) as well as at temperatures of 50° C. and 85° C. for a duration of 141 hours. Subjecting the photovoltaic cells 8 to heating at different temperatures allows them to be thermally degraded in order to determine their thermal stability.

The electrical conversion efficiency of the photovoltaic cells 8 comprising sodium hydroxide is measured before and after 141 hours of degradation under the various conditions.

The results are shown in the table below.

| Degradation | Jcc | Vco | | PCE |
|---|---|---|---|---|
| conditions | [mA/cm²] | [V] | FF | [%] |
| Reference | 13.29 | 0.76 | 0.64 | 6.43 |
| (initial | | | | |
| performance) | | | | |
| 141 hours at | 13.51 | 0.74 | 0.62 | 6.25 |
| ambient | | | | |
| temperature | | | | |
| 141 hours at | 13.40 | 0.75 | 0.64 | 6.47 |
| 50° C. | | | | |
| 141 hours at | 13.48 | 0.75 | 0.61 | 6.20 |
| 85° C. | | | | |

The results obtained show that the electrical conversion efficiency of the photovoltaic cells 8 comprising sodium hydroxide in the electron transport layer 16 is comparable to the electric conversion efficiency of a photovoltaic cell having an electron transport layer consisting solely of zinc oxide.

It can be seen that the addition of an additive to the electron transport layer 16 does not reduce the thermal stability of the photovoltaic cell 8 over time.

### Experiment 4

In one variant, a photovoltaic cell 8 according to the first embodiment, in which the additive is decamethyl cobaltocene, is produced.

The results obtained with decamethyl cobaltocene as the additive are shown in the table below.

| Molar ratio | Photo- | | | | |
|---|---|---|---|---|---|
| decamethyl | activation | | | | |
| cobaltocene: | time | Jcc | Vco | | PCE |
| ZnO [%] | [s] | [mA/cm²] | [V] | FF | [%] |
| 0 | 73.8 | 13.52 | 0.77 | 0.59 | 6.08 |
| 0.025 | 39.0 | 13.60 | 0.75 | 0.64 | 6.56 |
| 0.05 | 0 | 11.33 | 0.75 | 0.60 | 5.15 |
| 0.50 | 0 | 5.59 | 0.66 | 0.56 | 2.08 |
| 1.00 | 4.5 | 6.46 | 0.67 | 0.60 | 2.60 |

It can be seen that, for molar ratios of additive to metal oxide between 0.025% and 1.00%, the photovoltaic cells 8 according to the first embodiment have a photo-activation time of less than 1 minute.

1. A film for photovoltaic cell comprising:
at least one metal oxide, the metal oxide having a conduction band with a minimum energy level, and
at least one additive, the additive being selected from the group consisting of:
alkaline hydroxides,
alkaline earth hydroxides,
semi-conducting materials, said materials having a highest occupied molecular orbital, said molecular orbital having an energy level with an absolute value lower than the absolute value of the minimum energy level of the conduction band of the metal oxide, and
n-type doping materials, said materials having an ionization energy lower than the absolute value of the minimum energy level of the conduction band of the metal oxide.

2. The film according to claim 1, wherein the film consists of:
at least one metal oxide, the metal oxide having a conduction band with a minimum energy level, and
at least one additive, the additive being selected from the group consisting of:
alkaline hydroxides,
alkaline earth hydroxides,
n-type semiconducting materials, said materials having a highest occupied molecular orbital, said molecular orbital having an energy level with an absolute value lower than the absolute value of the minimum energy level of the conduction band of the metal oxide, and
n-type doping materials, said materials having an ionization energy lower than the absolute value of the minimum energy level of the conduction band of the metal oxide.

3. The film according to claim 1, wherein each metal oxide is chosen from zinc oxide, titanium oxide, tin oxide, derivatives and mixtures thereof.

4. The film according to claim 1, wherein the ratio between the additive content and the metal oxide content is less than or equal to 10.0%, the additive content being defined as the sum of the amounts of each additive and the metal oxide content being defined as the sum of the amounts of each metal oxide.

5. The film according to claim 4, wherein the ratio between the additive content and the metal oxide content is less than or equal to 1.0%.

6. The film according to claim 4, wherein the ratio between the additive content and the metal oxide content is greater than or equal to 0.01%.

7. Film according to claim 1, wherein each additive is a n-type dopant, said n-type dopant increasing the electron transport capacity of a doped material with said dopant compared to the electron transport capacity of an undoped material by a factor greater than or equal to 1.1.

8. The film according to claim 1, wherein each additive is a n-type dopant, said n-type dopant decreasing the photo-activation time of the doped material with said dopant compared to the photo-activation time of the undoped material by a factor greater than or equal to 1.1.

9. The film according to claim 1, wherein each additive is an alkaline hydroxide or an alkaline earth hydroxide.

10. The film according to claim 10, wherein each additive is selected from the group consisting of sodium hydroxide, potassium hydroxide, lithium hydroxide, and barium hydroxide.

11. The film according to claim 8, wherein the ratio between the additive content and the metal oxide content is greater than or equal to 0.05% and less than or equal to 1.0%, the additive content being defined as the sum of the amounts of each additive and the metal oxide content being defined as the sum of the amounts of each metal oxide.

12. The film according to claim 1, wherein the additive is decamethyl cobaltocene.

13. The film according to claim 1, wherein the film has a thickness comprised between 30 nanometers and 100 nanometers.

14. The film according to claim 13, wherein the thickness of the film is comprised between 35 nanometers and 45 nanometers.

15. A method for producing a film for photovoltaic cell, comprising the following steps:
preparing a mixture comprising at least one metal oxide, the metal oxide having a conduction band with a minimum energy level, and at least one additive, the additive being chosen from the group consisting of: alkaline hydroxides, alkaline earth hydroxides, and semi-conducting materials, said semi-conducting materials having a highest occupied molecular orbital, said molecular orbital having an energy level with an absolute value lower than the absolute value of the minimum energy level of the conduction band of the metal oxide, and
coating the mixture onto a substrate to form the film, the substrate being preferably an electrode made in an indium-tin alloy.

16. The method according to claim 15, wherein the method comprises a single step of heating following the step of coating, said single step of heating having a duration, the duration being less than or equal to 5 minutes.

17. The method according to claim 16, wherein the temperature at which the single heating step is carried out is constant.

18. A method for producing a film for photovoltaic cell, comprising the following steps:
preparing a mixture comprising at least one metal oxide, the metal oxide having a conduction band with a minimum energy level, and at least one additive, the additive being chosen from the n-type doping materials, said n-type doping materials having an ionization energy lower than the absolute value of the minimum energy level of the conduction band of the metal oxide, and
coating the mixture onto a substrate to form the film, the substrate being preferably an electrode made in an indium-tin alloy.

19. A photovoltaic cell comprising a film according to claim 1.

20. A photovoltaic module including at least one cell according to claim 19.
